(19) United States
(12) Patent Application Publication
(10) Pub. No.: US 2025/0038006 A1
(43) Pub. Date: Jan. 30, 2025

(54) METHOD FOR FORMING A MOLYBDENUM SILICIDE LAYER ON A SURFACE OF A SUBSTRATE

(71) Applicants: Didem Ernur, San Diego, CA (US); Jan Willem Maes, Wilrijk (BE)

(72) Inventors: Didem Ernur, San Diego, CA (US); Jan Willem Maes, Wilrijk (BE)

(21) Appl. No.: 18/783,002

(22) Filed: Jul. 24, 2024

Related U.S. Application Data
(60) Provisional application No. 63/516,482, filed on Jul. 28, 2023.

(51) Int. Cl. H01L 21/3205; C23C 16/02; C23C 16/18; C23C 16/455; C23C 16/56; H01L 21/02

(52) U.S. Cl. CPC H01L 21/32053; C23C 16/0227; C23C 16/18; C23C 16/45553; C23C 16/56; H01L 21/02068

(57) ABSTRACT

Methods for forming a molybdenum silicide layer on a surface of substrate are disclosed. The methods included seating a substrate within a reaction chamber, depositing a molybdenum metal layer on a surface of a substrate, and contacting a surface of the molybdenum metal layer with a silicon-containing gas thereby converting at least a portion of the molybdenum metal layer to a molybdenum silicide layer.

### CROSS-REFERENCE TO RELATED APPLICATION(S)

This application claims the benefit of U.S. Provisional Application 63/516,482 filed on Jul. 28, 2023, the entire contents of which are incorporated herein by reference.

### FIELD

The present disclosure relates generally to the field of semiconductor processing methods and systems, and to the field of device and integrated circuit manufacture. In particular, the present disclosure generally relates to methods for forming a molybdenum silicide layer on a surface of a substrate.

### BACKGROUND

Recently, molybdenum has gained interest as a metal for forming conductive layers during the manufacture of electronic devices. Molybdenum may work well for some applications. However, in some cases, device structures with deposited molybdenum may exhibit an undesirably high contact resistance. Accordingly, improved methods for forming conductive layers suitable for use in the manufacture of electronic devices are desired.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY

This summary may introduce a selection of concepts in a simplified form, which may be described in further detail below. This summary is not intended to necessarily identify key features or essential features of the claimed subject matter, nor is it intended to be used to limit the scope of the claimed subject matter.

Various embodiments of the present disclosure relate to methods of forming a molybdenum silicide layer on a surface of a substrate. As set forth in more detail below, methods described herein can be used during the manufacture of electronic devices. Such methods can reduce complexity and/or cost of manufacturing devices, and provide conductive layers with reduced contact resistance. By way of examples, methods described herein can be used in the formation of memory, logic, other gate-electrode devices, organic light emitting diodes, liquid crystal displays, thin film solar cells, other photovoltaic devices, and the like.

In accordance with examples of the disclosure, a method of forming a molybdenum silicide layer on a surface of a substrate is provided. An exemplary method includes seating a substrate within a reaction chamber, depositing a molybdenum metal layer on a surface of the substrate, and contacting the molybdenum metal layer with a silicon-containing gas to convert at least a portion of the molybdenum metal layer to a molybdenum silicide layer. In accordance with examples of the disclosure, the step of depositing the molybdenum metal layer can comprise a chemical vapor deposition process. In accordance with further examples of the disclosure, the step of depositing the molybdenum metal layer can comprise a thermal cyclical deposition process. In such cases, the thermal cyclical deposition process can comprise an atomic layer deposition process, each deposition cycle of the atomic layer process including, providing a molybdenum precursor to form an absorbed molybdenum species on the surface of substrate, and providing a reactant to react with the molybdenum species to form the molybdenum metal layer on the surface of the substrate. In accordance with examples of the disclosure, the step of depositing the molybdenum metal layer on a surface of a substrate can be performed at a substrate temperature between 150° C. and 400° C. In accordance with examples of the disclosure, the molybdenum precursor can include an oxygen-free molybdenum precursor. In such cases, the oxygen-free molybdenum precursor includes a molybdenum atom and a bis(ethyl benzene) ligand. In such cases, the oxygen-free molybdenum precursor can comprise Mo(EtBz)2. In accordance with examples of the disclosure, the reactant comprises a compound including a halogen atom and a hydrocarbon group. In such cases, the halogen atom can include iodine or bromine. Additionally, in such cases, the reactant can include iodobenzene or 1-iodobutane. Further, in such cases, the reactant can include bromobenzene or 1-bromobutane. In accordance with examples of the disclosure, the silicon-containing gas has a general formula RₐSiX_{b} or R_{c}X_{d}Si—SiR_{c}X_{d}, where each X can be independently selected from H, a halogen, or other ligand, wherein each R can be a C1-C12 organic group, and where a is 0, 1, 2 or 3, b is 4-a, c is 0, 1 or 2, and d is 3-c. In accordance with examples of the disclosure, the step of contacting the molybdenum metal layer with the silicon-containing gas is performed at a substrate temperature between 400° C. and 700° C. In such cases, the step of contacting the molybdenum metal layer with the silicon-containing gas is performed for a time period between 5 seconds and 600 seconds. In accordance with examples of the disclosure, the method can further comprise a step of depositing an additional molybdenum metal layer on the molybdenum silicide layer. In accordance with examples of the disclosure, the method can further comprise a step of cleaning a surface of the substrate prior to the step of depositing the molybdenum metal layer. In such cases, the step of cleaning the surface of the substrate can comprise contacting the surface of the substrate with first activated species formed using a fluorine-containing gas and second activated species formed using a hydrogen-containing or NH₃-containing gas. Additionally, in such cases, the first activated species formed using a fluorine-containing gas and the second activated species formed using a hydrogen-containing gas are formed using a remote plasma apparatus.

In accordance with additional examples of the disclosure, another method of forming a molybdenum silicide layer on a surface of a substrate is provided. The method includes seating a substrate within a reaction chamber, the substrate including a contact region of a semiconductor device structure. The methods further include cleaning a surface of the contact region using first activated species formed using a fluorine-containing gas and second activated species formed using a hydrogen-containing or NH₃-containing gas to form a cleaned contact surface. The method can further include, depositing a molybdenum metal layer directly on the cleaned contact surface by a cyclical deposition process comprising, heating the substrate to a substrate temperature between 150° C. and 400° C., providing an oxygen-free molybdenum precursor to the reaction chamber, providing a reactant to the reaction chamber, and contacting the molybdenum metal layer with a silicon-containing gas thereby converting at least a portion of the molybdenum metal layer to a molybdenum silicide layer, and depositing an additional molybdenum metal layer directly on the molybdenum silicide layer. In accordance with examples of the disclosure, the step of contacting the molybdenum metal layer with the silicon-containing gas is performed at a substrate temperature between 400° C. and 700° C.

These and other embodiments will become readily apparent to those skilled in the art from the following detailed description of certain embodiments having reference to the attached figures. The invention is not limited to any particular embodiments disclosed.

### BRIEF DESCRIPTION OF DRAWING

A more complete understanding of the embodiments of the present disclosure may be derived by referring to the detailed description and claims when considered in connection with the following illustrative figures.

FIG. 1 illustrates a method in accordance with exemplary embodiments of the disclosure.

FIGS. 2-5 illustrate structures in accordance with examples of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of methods, structures, devices, and apparatus provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

As set forth in more detail below, various embodiments of the disclosure provide methods for forming a molybdenum silicide layer on a surface of a substrate. Exemplary methods can be used to form a molybdenum silicide layer on a surface of a substrate employing a vapor-solid reaction. For example, exemplary methods of the present disclosure can include depositing a molybdenum metal layer on a surface of a substrate and subsequently contacting the deposited molybdenum metal layer with a silicon-containing gas which reacts with the molybdenum metal layer via a vapor-solid reaction to form the molybdenum silicide layer.

The formation of a molybdenum silicide layer by employing vapor-solid reactions can result in a formation process which has a reduced thermal budget in comparison with other methods. For example, the direct deposition of a molybdenum silicide layer by chemical vapor deposition processes or atomic layer deposition processes may necessitate high temperature deposition processes. As a further example, the formation of a molybdenum silicide film by the high temperature reaction between a deposited molybdenum layer and an underlying silicon substrate results in a portion of the silicon substrate being consumed during the reaction which can alter the thickness of the underlying silicon substrate and alter doping profiles of the silicon substrate. When employing a molybdenum silicide layer as a component layer of an electrical contact stack to a semiconductor device structure, such as on the source/drain regions of a transistor, such a change in thickness and/or doping profile of the source/drain regions can negatively impact device performance, uniformity, and yield.

Additionally or alternatively, exemplary methods can be used to form a molybdenum silicide layer on a clean (e.g., having a (e.g., native) oxide removed) surface. Methods described herein can be used to form a molybdenum silicide layer to reduce contact resistance of a contact stack comprising molybdenum. Additionally or alternatively, methods can be employed to form a molybdenum silicide layer using a relatively simple process and/or with reduced equipment requirements. Further, in at least some cases, the molybdenum silicide layer can be formed at a relatively low temperature.

Molybdenum silicide formed in accordance with a method described herein may be particularly well suited for back end of line and middle end of line processing of electronic devices, such as semiconductor devices. By way of particular examples, methods described herein can be used during the formation of logic devices and memory devices, such as dynamic random access memory (DRAM) devices.

In this disclosure, gas can include material that is a gas at normal temperature and pressure (NTP), a vaporized solid and/or a vaporized liquid, and can be constituted by a single gas or a mixture of gases, depending on the context.

The terms precursor and reactant can refer to molecules (compounds or molecules comprising a single element) that participate in a chemical reaction that produces another compound. A precursor typically contains portions that are at least partly incorporated into the compound or element resulting from the chemical reaction in question. Such a resulting compound or element may be deposited on a substrate. A reactant may be an element or a compound that is not incorporated into the resulting compound or element to a significant extent. In some cases, the term reactant can be used interchangeably with the term precursor.

As used herein, a molybdenum precursor includes a gas or a material that can become gaseous and that can be represented by a chemical formula that includes molybdenum. An oxygen-free molybdenum precursor includes a molybdenum compound that does not include oxygen in its chemical formula.

As used herein, a silicon-containing gas includes a gas or a material that can become gaseous and that can be represented by a chemical formula that includes silicon.

As used herein, the term “substrate” can refer to any underlying material or materials that can be used to form, or upon which, a device, a circuit, or a film can be formed by means of a method according to an embodiment of the present disclosure. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of example, a substrate can include bulk semiconductor material and an insulating or dielectric material layer overlying at least a portion of the bulk semiconductor material. Further, the term “substrate” may refer to any underlying material or materials that may be used, or upon which, a device, a circuit, or a film may be formed. The “substrate” may be continuous or non-continuous; rigid or flexible; solid or porous. The “substrate” may be in any form such as a powder, a plate, or a workpiece. Substrates in the form of a plate may include wafers in various shapes and sizes. Substrates may be made from materials, such as silicon, silicon germanium, silicon oxide, gallium arsenide, gallium nitride and silicon carbide for example. A continuous substrate may extend beyond the bounds of a process chamber where a deposition process occurs and may move through the process chamber such that the process continues until the end of the substrate is reached. A continuous substrate may be supplied from a continuous substrate feeding system allowing for manufacture and output of the continuous substrate in any appropriate form. Non-limiting examples of a continuous substrate may include a sheet, a non-woven film, a roll, a foil, a web, a flexible material, a bundle of continuous filaments or fibers (i.e., ceramic fibers or polymer fibers). Continuous substrates may also comprise carriers or sheets upon which non-continuous substrates are mounted. By way of examples, a substrate can include semiconductor material. The semiconductor material can include or be used to form one or more of a source, drain, or channel region of a device. The substrate can further include an interlayer dielectric (e.g., silicon oxide) and/or a high dielectric constant material layer overlying the semiconductor material. In this context, high dielectric constant material or high k dielectric material is material having a dielectric constant greater than the dielectric constant of silicon dioxide.

As used herein, the term “layer” can refer to any continuous or non-continuous structure and material, such as material formed and/or deposited by the methods disclosed herein. For example, a layer can include two-dimensional materials, three-dimensional materials, nanoparticles or even partial or full molecular layers or partial or full atomic layers or clusters of atoms and/or molecules. A layer may comprise material or a layer with pinholes. A layer may be at least partially continuous. A layer may be patterned, e.g., subdivided, and may be comprised of a plurality of semiconductor devices.

As used herein, a structure can be or include a substrate as described herein. Structures can include a substrate and one or more layers overlying the substrate, such as one or more layers formed by a method according to the current disclosure. The structure may include or be used in the formation of, for example, a via or a line in BEOL processing, or a contact or a local interconnect in MEOL processing. The structure may also be used to form a layer in a gate electrode, a buried power rail in logic applications, as well as a word line or a bit line in an advanced memory application.

As used herein, a cyclical deposition process and cyclical deposition can refer to the sequential introduction of precursors (and/or reactants) into a reaction chamber to deposit a layer over a substrate and includes processing techniques, such as atomic layer deposition (ALD), spatial ALD, cyclical chemical vapor deposition (cyclical CVD), and hybrid cyclical deposition processes that include an ALD component and a cyclical CVD component. In some cases, a cyclical deposition process can include continually flowing one or more precursors, reactants, or inert gases, and pulsing other of the precursors or reactants. In addition, the term thermal cyclical deposition process can refer to the sequential introduction of precursors (and/or reactants) into a reaction chamber in a plasma-free environment, i.e., without employing plasma activated species in the deposition cycles comprising the thermal cyclical deposition process.

As used herein, the term purge can refer to a procedure in which an inert or substantially inert gas is provided to a reaction chamber in between two pulses of gases that might otherwise react with each other. For example, a purge, e.g., using an inert gas, such as a noble gas, may be provided between a precursor pulse and a reactant pulse to reduce gas phase interactions between the precursor and the reactant that might otherwise occur. It shall be understood that a purge can be effective either in time or in space, or both. For example, in the case of temporal purges, a purge step can be used, e.g., in the temporal sequence of providing a precursor to a reaction chamber, providing a purge gas to the reaction chamber, and providing a reactant or another precursor to the reaction chamber, wherein the substrate on which a layer is deposited does not move. In the case of spatial purges, a purge step can take the following form: moving a substrate from a first location to which a precursor is (e.g., continually) supplied, through a purge gas curtain, to a second location to which a reactant or other precursor is (e.g., continually) supplied.

Further, in this disclosure, any two numbers of a variable can constitute a workable range of the variable, and any ranges indicated may include or exclude the endpoints. Additionally, any values of variables indicated (regardless of whether they are indicated with the term about or not) may refer to precise values or approximate values and include equivalents, and may refer to average, median, representative, majority, or the like. Further, in this disclosure, the terms including, constituted by and having refer independently to typically or broadly comprising, comprising, consisting essentially of, or consisting of in some embodiments.

In this disclosure, any defined meanings do not necessarily exclude ordinary and customary meanings, in some embodiments.

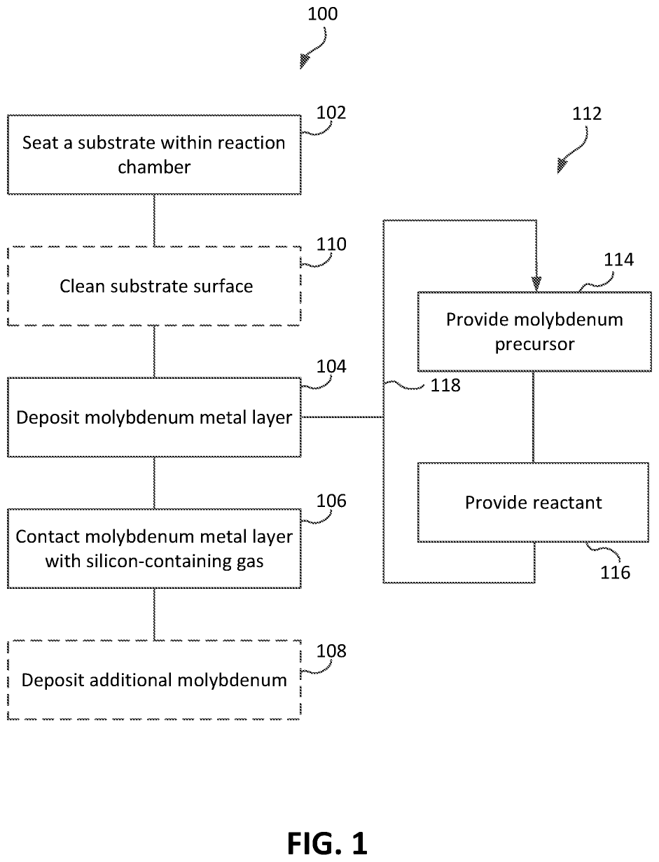

Turning now to the figures, FIG. 1 illustrates a method 100. Method 100 includes the steps of seating a substrate within a reaction chamber (step 102), depositing a molybdenum metal layer on a surface of the substrate (step 104), contacting the molybdenum metal layer with a silicon-containing gas (step 106), and optionally depositing an additional molybdenum metal layer (step 108). Further, method 100 can optionally include a step of cleaning a substrate surface (step 110).

During step 102, a substrate is seated within a reaction chamber. The reaction chamber used during step 102 can be or include a reaction chamber of a chemical vapor deposition reactor system configured to perform a chemical vapor deposition process or a cyclical deposition process. In some embodiments, the reaction chamber used during step 102 can be or include a reaction chamber of an atomic layer deposition reactor system configured to perform a cyclical deposition process.

The reaction chamber can be a standalone reaction chamber or part of a cluster tool. The reaction chamber can include a substrate heater to heat a substrate to a substrate temperature noted herein. Additionally or alternatively, the reaction chamber can include thermal processing apparatus, such as lamps, to heat the substrate.

The substrate seated within the reaction chamber during step 102 can include a contact region (or multiple contact regions) of a semiconductor device structure. The contact region can include a source/drain region of a semiconductor device structure. In some embodiments, the substrate includes a plurality of partially fabricated semiconductor device structure including one or more contact regions, such as, for example, one or more source/drain regions. For example, the source/drain regions can comprise doped (p-type or n-type) silicon, germanium, silicon germanium, and may also comprise a surface layer (e.g., native oxide thereof). A source/drain region can include both a source region and a drain region upon which electrical contacts are formed. For example, one or more electrical contact layers formed on (or directly on) a surface of the source/drain region can include the molybdenum silicide layers (and option additional layers) formed by the methods described herein.

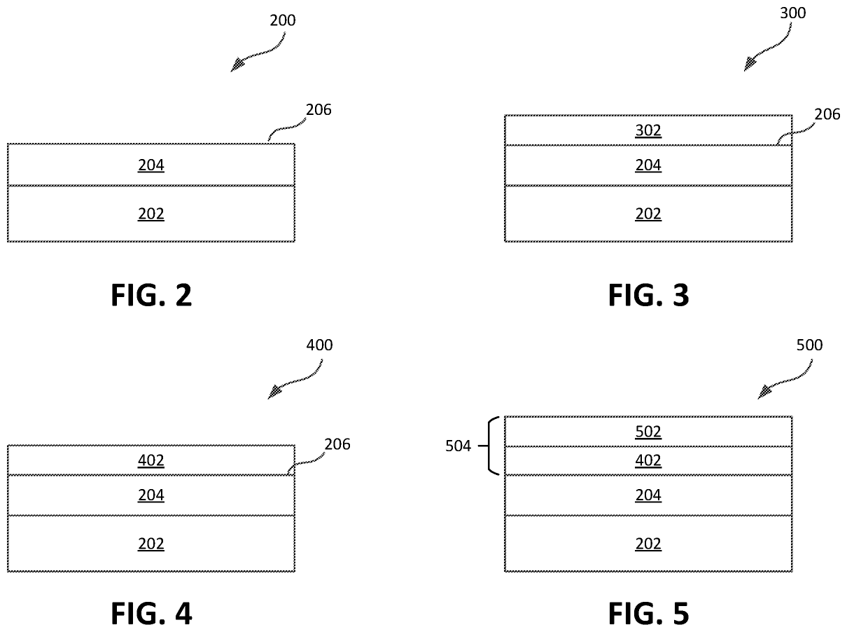

FIG. 2 illustrates a portion of a substrate suitable for use as a substrate during step 102. Substrate 200 includes a semiconductor body 202 and a contact region 204 disposed on the semiconductor body. The contact region 204 can include a source/drain region of a semiconductor device structure. For example, contact region 204 can comprise doped (p-type or n-type) silicon, germanium, silicon germanium, and may also comprise a surface 206, which can comprise a native oxide, for example. In such cases, the contact region 204 can form part of a semiconductor device structure, such as, a gate-all-around transistor, a nanosheet transistor, a forksheet transistor, a complementary FET (CFET) device, and/or a memory device (e.g., DRAM). As illustrated in FIG. 2, no liner or barrier layer may be present, such that the molybdenum silicide layer and subsequently formed additional molybdenum metal layer can be in direct contact with the contact region 204. This allows for obtaining a low contact resistance and/or relatively less complex manufacturing, compared to typical processing that require a barrier layer between a metal and, for example, an interlayer dielectric layer.

Prior to depositing the molybdenum metal layer on a surface of the substrate (step 104), a surface of the substrate may undergo an optional cleaning step to remove surface contaminants, such as, a native oxide layer, for example. Therefore, in some embodiments, the method 100 can also include the optional step 110 of cleaning a surface of the substrate before the step of depositing a molybdenum metal layer (step 104). Step 110 can be performed within the reaction chamber or within another reaction chamber—e.g., within the same system module. In accordance with examples of the disclosure, when optionally cleaning a surface of the substrate (step 110) within another reaction chamber, optional cleaning the surface of the substrate can be performed prior to seating the substrate within the reaction chamber employed for the deposition of the molybdenum metal layer.

During the optional cleaning step 110, a first activated species formed using a fluorine-containing gas and a second activated species formed using a hydrogen-containing or NH₃-containing gas are formed within or provided to the reaction chamber to form a cleaned surface. Surfaces cleaned in accordance with examples described herein can produce higher quality (e.g., less oxygen at an interface) molybdenum silicides, compared to molybdenum silicides formed using, for example, HF as an etchant. In accordance with examples of the disclosure, the surface 206 of the contact region 204 illustrated in FIG. 2 can be cleaned during the cleaning step 110 to remove any contaminates, such as a native oxide, from the surface 206. In such cases, step 110 can comprise, cleaning a surface of the contact region 204 using first activated species formed using a fluorine-containing gas and second activated species formed using a hydrogen containing or NH₃-containing gas to form a cleaned contact surface.

In accordance with examples of the disclosure, the first activated species formed using a fluorine-containing gas and the second activated species formed using a hydrogen-containing or NH₃-containing gas to form a cleaned surface are formed using an indirect or remote plasma apparatus. A power used to form a plasma can be about 10 to about 1000 W or about 20 to about 200 W for a 300 mm diameter substrate. A duration of a plasma on-time can be about 1 to about 60 or about 2 to about 10 seconds.

The fluorine-containing gas can be or include, for example, one or more of NF₃, XeF₃, F₂, or the like. A flow rate of the fluorine-containing gas to the remote or indirect plasma apparatus can be about 1 to about 1000 or about 2 to about 100 sccm.

The hydrogen-containing gas can be or include one or more of NH₃, N₂/H₂ (e.g., 10-90 vol. % H2), hydrazine, a substituted hydrazine and/or triazine as described herein, or the like. A flow rate of the hydrogen-containing gas to the remote or indirect plasma apparatus can be about 1 to about 1000 or about 10 to about 200 sccm.

The fluorine-containing gas and the hydrogen-containing or NH₃-containing gas can be supplied to a plasma apparatus sequentially and/or to separate plasma apparatus or to different regions of a plasma apparatus. The plasma apparatus can include one or more dedicated regions or units, which can be dedicated to forming respective active species. Alternatively, the first activated species formed using a fluorine-containing gas and the second activated species formed using a hydrogen-containing gas can be formed using the same plasma unit or region.

Once the substrate is seated within the reaction chamber (step 102), and optionally undergone a cleaning process (step 110), method 100 can continue with the step of depositing a molybdenum metal layer on a surface of the substrate (step 104).

The step of depositing the molybdenum metal layer (step 104) can be performed at a substrate temperature between 100° C. and 500° C., or between 150° C. and 400° C., or between 250° C. and 350° C., or between 275° C. and 325° C., or between 280° C. and 320° C. In some embodiments, the step of depositing the molybdenum metal layer (step 104) can be performed at a substrate temperature of less than 500° C., or less than 400° C., or less than 300° C., or less than 200° C., or less than 100° C.

In addition to controlling the temperature of the substrate, a pressure within the reaction chamber may also be regulated. For example, in some embodiments of the disclosure, the pressure within the reaction chamber during step 102 may be less than 760 Torr or between 0.2 Torr and 760 Torr, about 1 Torr and 100 Torr, or about 1 Torr and 10 Torr.

In accordance with examples of the disclosure, the step of depositing the molybdenum metal layer (step 104) can comprise a chemical vapor deposition process.

In accordance with further examples of the disclosure, the step of depositing the molybdenum metal layer on a surface of a substrate (step 104) can include a thermal deposition process, such as thermal cyclical deposition process. In thermal deposition processes, the chemical reactions are promoted by increased temperature relevant to ambient temperature. Generally, temperature increase provides the energy for the formation of a molybdenum metal layer and the subsequent formation of a molybdenum silicide layer in the absence of other external energy sources, such as plasma, radicals, or other forms of radiation. In some embodiments, the cleaning step 110 includes forming a plasma to form activated species as described above.

In accordance with further examples of the disclosure, and referring to FIG. 1, the step of depositing the molybdenum metal layer (step 104) can comprise a cyclical deposition process. In accordance with examples of the disclosure, the step of depositing the molybdenum metal layer (step 104) can comprise a thermal cyclical deposition process. In such examples of the disclosure and referring to FIG. 1, the step of depositing a molybdenum metal layer 104 on a surface of the substrate comprises a cyclical deposition process 112, such as an atomic layer deposition process, that includes providing an molybdenum precursor to form an absorbed molybdenum species on the surface of the substrate (step 114) and providing a reactant to react with the molybdenum species to form the molybdenum metal layer on the surface of the substrate (step 116). Steps 114 and 116 can be repeated as illustrated by loop 118, each loop comprising an individual deposition cycle of the cyclical deposition process 112, such as an atomic layer deposition process. Further, steps 114 and 116 can be initiated and/or terminated in any order. Yet further, cyclical deposition process 112 can include one or more (e.g., 1-10 or 1-5) steps 114 and/or 116 prior to proceeding to the other of step 114 or 116.

During step 114, a molybdenum precursor is provided to the reaction chamber. The temperature and pressure within the reaction chamber can be as described above in connection with step 104.

In some embodiments, the molybdenum precursor is provided as a single compound or as mixture of two or more compounds. In a mixture, the other compound(s) in addition to the molybdenum compound may be one or more inert compounds or elements—i.e., inert gases. In some embodiments, the molybdenum precursor is provided in a composition. Compositions suitable for use as composition can include a molybdenum compound and an effective amount of one or more stabilizing agents and/or inert or carrier gases, such as argon, nitrogen, and/or hydrogen. Composition may be a solution or a gas at NTP.

In accordance with examples of the disclosure, the molybdenum precursor can comprise a molybdenum halide precursor. In further examples, the molybdenum halide precursor can comprise a molybdenum chalcogenide and in some embodiments the molybdenum halide precursor can comprise a molybdenum chalcogenide halide. For example, the molybdenum chalcogenide halide precursor can include a molybdenum oxyhalide selected from a group consisting of a molybdenum oxychloride, a molybdenum oxyiodide, and a molybdenum oxybromide. In example embodiments, the molybdenum halide precursor can comprise a molybdenum oxychloride, including, but not limited to, molybdenum (V) trichloride oxide (MoOCl₃), molybdenum (VI) tetrachloride oxide (MoOCl₄), and molybdenum (IV) dichloride dioxide (MoO₂Cl₂).

In accordance with further examples of the disclosure, the molybdenum precursor can include an oxygen-free molybdenum precursor. In such cases, the oxygen-free molybdenum compound comprises a molybdenum atom and an organic (e.g., hydrocarbon) ligand. In some embodiments, the molybdenum precursor comprises a metal-organic compound comprising molybdenum. In such cases, the molybdenum precursor can be referred to as a metal-organic molybdenum precursor. An oxygen-free metal-organic molybdenum precursor is herein meant to include a molybdenum compound comprising a molybdenum atom and a hydrocarbon ligand, wherein the molybdenum atom is not directly bonded to a carbon atom. In some embodiments, the oxygen-free metal-organic molybdenum precursor comprises one molybdenum atom, which is not directly bonded with a carbon atom. In some embodiments, the oxygen-free metal-organic molybdenum precursor comprises two or more molybdenum atoms, none of which is directly bonded to a carbon atom. In some embodiments, the oxygen-free metal-organic molybdenum precursor comprises two or more metal atoms, wherein at least one metal atom is not directly bonded to a carbon atom.

In some embodiments, the oxygen-free molybdenum precursor comprises an oxygen-free organometallic molybdenum compound comprising molybdenum. An oxygen-free organometallic molybdenum precursor is herein meant to refer to a molybdenum compound comprising a molybdenum atom and an organic (e.g., hydrocarbon) ligand, wherein the molybdenum atom is directly bonded to a carbon atom. In embodiments in which an oxygen-free molybdenum organometallic precursor comprises two or more metal atoms, one or more (e.g., all) of the metal atoms can be directly bonded with a carbon atom. In some embodiments, oxygen-free molybdenum organometallic precursor comprise only molybdenum, carbon and hydrogen. In other words, oxygen-free molybdenum organometallic precursor does not contain oxygen, nitrogen or other additional elements. In some embodiments, the oxygen-free molybdenum organometallic precursor comprises at least two hydrocarbon ligands. In some embodiments, the oxygen-free molybdenum organometallic precursor comprises at least three hydrocarbon ligands. In some embodiments, the oxygen-free molybdenum organometallic precursor comprises four hydrocarbon ligands. In some embodiments, the oxygen-free molybdenum organometallic precursor comprises a hydrocarbon ligand and a hydride ligand. In some embodiments, the oxygen-free molybdenum organometallic precursor comprises a hydrocarbon ligand and two or more hydride ligands. In some embodiments, the oxygen-free molybdenum organometallic precursor comprises two hydrocarbon ligands and two hydride ligands. Hydrocarbon ligands as described herein can be or include, for example, C1-C10 hydrocarbons.

In some embodiments, the oxygen-free molybdenum precursor comprises one or more cyclic portions. For example, the oxygen-free molybdenum precursor may comprise one or more benzene rings. In some embodiments, the oxygen-free molybdenum precursor comprises two benzene rings. One or both benzene rings may comprise (e.g., C1-C6) hydrocarbon substituents. In some embodiments, each benzene ring of the oxygen-free molybdenum precursor comprises an alkyl substituent. An alkyl substituent may be a methyl group, an ethyl group, or a linear or branched alkyl group comprising three, four, five or six carbon atoms. For example, the alkyl substituent of the benzene ring may be an n-propyl group or an iso-propyl group. Further, the alkyl substituent may be an n-, iso-, tert- or sec-form of a butyl, pentyl or hexyl moiety. In some embodiments, the molybdenum precursor comprises, consists essentially of, or consists of bis(ethylbenzene)molybdenum.

In some embodiments, the oxygen-free molybdenum precursor comprises a cyclopentadienyl (Cp) ligand. For example, the oxygen-free molybdenum precursor may comprise, consist essentially of, or consist of MoCp₂Cl₂ or MoCp₂H₂, Mo(iPrCp)₂Cl₂, Mo(iPrCp)₂H₂, Mo(EtCp)₂H₂.

In some embodiments, the oxygen-free molybdenum precursor comprises a halogenated molybdenum compound comprising or consisting of molybdenum and one or more halogen atoms. The oxygen-free molybdenum precursor can include one or more ligands noted above and one or more halogen atoms. Alternatively, the oxygen-free molybdenum precursor compound can consist of molybdenum and one or more halogen atoms. In some embodiments, the oxygen-free molybdenum precursor comprises a molybdenum chloride compound, a molybdenum iodide compound, or a molybdenum bromide compound. As non-limiting examples, the molybdenum halide precursor may comprise at least one of: molybdenum pentachloride (MoCl₅), molybdenum hexachloride (MoCl₆), molybdenum hexafluoride (MoF₆), molybdenum triiodide (MoI₃), or molybdenum dibromide (MoBr₂). In some embodiments, the molybdenum halide precursor may comprise a molybdenum chalcogenide, and in particular embodiments, the molybdenum halide precursor may comprise a molybdenum chalcogenide halide that does not include oxygen. Exemplary chalcogenides include sulfur, selenium, and tellurium.

A duration of step 114 during each deposition cycle of cyclical deposition process 112 can be between about 0.1 seconds and about 60 seconds, between about 0.1 seconds and about 10 seconds, or between about 0.5 seconds and about 5.0 seconds. A flow rate of the oxygen-free molybdenum precursor to the reaction chamber can be less than 1000 sccm, or less than 500 sccm, or less than 100 sccm, or less than 10 sccm, or even less than 1 sccm or range from about 1 to 2000 sccm, from about 5 to 1000 sccm, or from about 10 to about 500 sccm.

During step 116, a reactant is provided to the reaction chamber. Exemplary reactants suitable for use in step 116 can include reducing agents. Exemplary reducing agents include one or more of forming gas (H₂+N₂), ammonia (NH₃), hydrazine (N₂H₄), an alkyl-hydrazine (e.g., tertiary butyl hydrazine (C₄H₁₂N₂)), molecular hydrogen (H₂), hydrogen atoms (H), (e.g., C1-C4) alcohols, (e.g., C1-C4) aldehydes, (e.g., C1-C4) carboxylic acids, (e.g., B1-B12) boranes, or an amine.

In accordance with further examples of the disclosure, the react can comprise a halogen reactant. In some embodiments, the halogen reactant comprises a halogenated hydrocarbon comprising only one halogen atom. The halogen reactant may comprise two or three carbon atoms. Further, the halogen reactant may comprise four, five, six, seven or eight carbon atoms. The halogen reactant may comprise a linear, branched, cyclical and/or aromatic carbon chain. For example, the halogen reactant may comprise a halogenated ethane, propane, benzene, 2-methylpropane, 2,2-dimethylpropane (neopentane), n-butane, 2-methylbutane, 2,2-dimethylbutane, n-pentane, 2-methylpantane, 3-methylpentane or an n-hexane. In some embodiments, the hydrocarbon comprises and aryl group. In some embodiments, the halogen reactant comprises halobenzene.

In some embodiments, the halogen reactant comprises only one halogen atom. The halogen atom is selected from the group consisting of bromine, iodine, fluorine or chlorine. The location of the said one carbon atom in a carbon chain may vary. In some embodiments, it is located at the end of a carbon chain, but in some embodiments, it is located away from the end of the carbon chain. In the case of a cyclic hydrocarbon, the halogen may be located at any of the carbon atoms. As is evident to those skilled in the art, the position of a given carbon atom in a carbon chain limits the number of potential substituents available. In some embodiments, the halogen reactant comprises, consists essentially of, or consists of iodobenzene or 1-iodobutane. In some embodiments, the halogen reactant comprises, consists essentially of, or consists of bromobenzene or 1-bromobutane.

In some embodiments, the halogen reactant comprises an allyl halide. The halogen reactant may comprise one halogen atom attached to the corresponding amount of allylic carbons in an allyl halide.

In some embodiments, the halogen reactant comprises a vinyl halide. The halogen reactant may comprise one halogen atom attached to the corresponding amount of vinylic carbons in a vinyl halide.

During step 116, a flow rate of the reactant to the reaction chamber can be greater than zero and less than 30 slm, or less than 15 slm, or less than 10 slm, or less than 5 slm, or less than 1 slm, or even less than 0.1 slm. For example, the flow rate can be between about 0.1 to 30 slm, from about 5 to 15 slm, or equal to or greater than 10 slm. In the case of cyclical deposition processes, the reactant can be pulsed—e.g., for a duration between about 0.01 seconds and about 180 seconds, between about 0.05 seconds and about 60 seconds, or between about 0.1 seconds and about 30 seconds.

The oxygen-free molybdenum precursor and/or reactant can be purged from the reaction chamber—e.g., after each pulse and/or upon completion of a step 114, 116 and/or each deposition cycle of the cyclical deposition process (step 112). A purge can be effective either in time or in space, or both. Purging times can be, for example, from about 0.01 seconds to about 20 seconds, from about 0.05 seconds to about 20 seconds, or from about 1 second to about 20 seconds, or from about 0.5 seconds to about 10 seconds, or from about 1 second to about 7 seconds. A flow rate of a purge gas to the reaction chamber can be less than 1000 sccm, or less than 500 sccm, or less than 100 sccm, or less than 10 sccm, or even less than 1 sccm or range from about 1 to 2000 sccm, from about 5 to 1000 sccm, or from about 10 to about 500 sccm.

In some embodiments, the oxygen-free molybdenum precursor may be pulsed more than one time, for example two, three or four times, before a reactant is pulsed to the reaction chamber. Similarly, there may be more than one pulse, such as two, three or four pulses, of a reactant before an oxygen-free molybdenum precursor is pulsed (i.e., provided) to the reaction chamber.

The cyclical deposition process (step 112) is repeated until an end criteria is met. For example, the end criteria can be based on a number of deposition cycles performed, or by the desired thickness of the molybdenum metal film deposited.

FIG. 3 illustrates a structure 300 after the completion of step 104. As illustrated, a molybdenum metal layer 302 is deposited on the cleaned contact surface 206 of the contact region 204.

The molybdenum metal layer 302 may be at least partly in elemental form. Thus, the oxidation state of molybdenum metal layer may be zero. Thus, molybdenum metal layer 302 can comprise, consist essentially of, or consist of molybdenum. In accordance with examples of the disclosure, the molybdenum metal layer 302 comprises, for example, about 60 to about 99 atomic percentage (at. %) molybdenum, or about 75 to about 99 at. % molybdenum, or about 75 to about 95 at. % molybdenum, or about 80 to about 95 at. % molybdenum. The molybdenum layer 302 deposited by a method according to the current disclosure may comprise, for example about 80 at. %, about 83 at. %, about 85 at. %, about 87 at. %, about 90 at. %, about 95 at. %, about 97 at. % or about 99 at. % molybdenum. A molybdenum metal layer consisting of molybdenum may include an acceptable amount of impurities, such as carbon, chlorine or other halogen, and/or hydrogen that may originate from one or more precursors used to deposit the molybdenum layer.

In some embodiments, the molybdenum metal layer 302 may comprise less than about 20 at. %, less than about 15 at. %, less than about 10 at. %, less than about 8 at. %, less than about 6 at. %, less than about 5 at. %, less than about 4.5 at. %, or less than about 3 at. % carbon.

In accordance with examples of the disclosure, the cyclical deposition process 112 can comprise depositing a molybdenum metal layer 302 (FIG. 3) on a surface of the substrate (e.g., the cleaned contact surface 206) to an average layer thickness between 1 nm and 50 nm, or between 2 nm and 25 nm, or between 3 nm and 15 nm. In accordance with examples of the disclosure, the molybdenum metal layer is deposited to an average layer thickness between 1 nm and 10 nm, or between 2 nm and 8 nm, or between 3 nm and 5 nm. In accordance with examples of the disclosure, the molybdenum metal layer is deposited to an average layer thickness of less than 10 nm, or less 8 nm, or less 6 nm, or less than 4 nm, or less than 2 nm, or less than 1 nm.

Upon completion of the deposition of the molybdenum metal layer (step 104), method 100 continues with step 106 which comprising contacting the molybdenum metal layer with a silicon-containing gas thereby converting at least a portion of the molybdenum metal layer to a molybdenum silicide layer. The step of contacting the molybdenum metal layer with the silicon-containing gas (step 106) includes providing the silicon-containing gas to the reaction chamber wherein the silicon-containing contacts the molybdenum metal layer disposed on the substrate. In accordance with examples of the disclosure, contacting the molybdenum metal layer with the silicon-containing gas causes a vapor-solid reaction between the molybdenum metal layer and the silicon-containing gas. In such cases, the vapor-solid reaction results in the conversion of the molybdenum metal layer to a metal silicide layer. In such cases, parameters including, but not limited to, the substrate temperature, pressure, selection of silicon-containing gas, and the duration of contact between silicon-containing gas and molybdenum metal layer can be tuned to convert at least a portion of the molybdenum metal layer to a metal silicide layer. Further in such cases, the substrate temperature and the duration of contact between silicon-containing gas and molybdenum metal layer can be tuned to convert the total thickness of the molybdenum metal layer to a molybdenum silicide layer. The term “total thickness” as used in this context refers to the total volume of the molybdenum metal layer and likewise “converting the total thickness of the molybdenum metal layer to a molybdenum silicide layer” refers to the complete conversion of the molybdenum metal layer to a molybdenum silicide layer.

The step of contacting the molybdenum metal layer with a silicon-containing gas (step 106) can be performed at a substrate temperature between 300° C. and 800° C., or between 350° C. and 750° C., or between 400° C. and 700° C. In some embodiments, the step of contacting the molybdenum metal layer with a silicon-containing gas (step 114) can be performed at a substrate temperature of less than 800° C., or less than 700° C., or less than 600° C., or less than 500° C., or less than 400° C.

In accordance with examples of the disclosure, the molybdenum metal layer can be deposited on a substrate which includes memory device structure, such as, for example, dynamic random access memory (DRAM) device structures. In such cases, the step of contacting the molybdenum metal layer with the silicon-containing gas (step 106) can be performed at a substrate temperature less than 700° C., or less than 600° C., or less than 500° C., or less than 400° C., or between 400° C. and 700° C.

In accordance with further examples of the disclosure, the molybdenum metal layer can be deposited on a substrate which includes logic devices, such as, for example, transistor device structures. In such cases, the step of contacting the molybdenum metal layer with the silicon-containing gas (step 106) can be performed at a substrate temperature less than 450° C., or less than 400° C., or less than 350° C., or less than 300° C., or less than 200° C., or between 200° C. and 450° C.

In addition to controlling the temperature of the substrate, a pressure within the reaction chamber may also be regulated. For example, in some embodiments of the disclosure, the pressure within the reaction chamber during step 106 may be less than 760 Torr or between 0.2 Torr and 760 Torr, about 1 Torr and 100 Torr, or about 1 Torr and 10 Torr. In some embodiments, the pressure within the reaction chamber during step 106 is less than atmosphere, or between 0.1 mTorr and 10 Torr, or between 0.1 Torr and 5 Torr, or between 1 and 2 Torr.

During step 106, a silicon-containing gas is provided to the reaction chamber wherein the gas makes contact with the molybdenum metal layer. In some cases, the silicon-containing gas comprises a compound having a general formula RₐSiX_{b} or R_{c}X_{d}Si—SiR_{c}X_{d}, where each X can be independently selected from H, a halogen, or other ligand, wherein each R can be a C1-C12 organic group, and where a is 0, 1, 2 or 3, b is 4-a, c is 0, 1 or 2, and d is 3-c. R may be a hydrocarbon. If a is two or three, or c is two, each R can be selected independently. In some embodiments, each R is selected from alkyls and aryls. For clarity, X may represent different (e.g., independently selected) ligands. Thus, in some embodiments, an auxiliary reactant may be, for example, SiH₂Br₂, SiH₂I₂ or SiH₂Cl₂.

In some embodiments, X is a hydrogen, a substituted or an unsubstituted alkyl or aryl or a halogen. In some embodiments, X is H. In some embodiments, X is an alkyl or an aryl. In some embodiments, X is a C1 to C4 alkyl. In some embodiments, X is a substituted alkyl or aryl. In some embodiments, X is a substituted alkyl or aryl, wherein the substituent comprises silicon. In some embodiments, X is selected from a group consisting of H, Me, Et, nPr, iPr, nBu, tBu, M′Me₃, M′Et₃, M′Pr₃, M′Bu₃, Cl, Br, or I, wherein M′ is Si.

In some embodiments, the silicon-containing gas may have a formula R₃Six, R₂SiX₂, R_{S}iX₃, or SiX₄, where a, b, R and X are as above. In some embodiments, a silicon atom does not comprise four identical substituents. In some embodiments, the silicon-containing gas is not SiH₄. In some embodiments, the silicon-containing gas is not SiH₂Me₂. In some embodiments, the silicon-containing gas is not SiH₂Et₂. In some embodiments, the silicon-containing gas is not Si₂H₂.

In some cases, exemplary silicon-containing gases suitable for use during step 106 can consist of silicon and hydrogen. For example, the silicon-containing gas may comprise a silane, such as, for example, silane (SiH₄), disilane (Si₂H₆), trisilane (Si₃H₈), tetrasilane (Si₄H₁₀) or higher order silanes with the general empirical formula SiₓH₍₂ₓ₊₂₎.

In some cases, the silicon-containing gas can include an amino silane, such as one or more of silanediamine N,N,N′,N-tetraethyl (C₈H₂₂N₂Si), BTBAS (bis(tertiarybutylamino)silane), BDEAS (bis(diethylamino)silane), or TDMAS (tris(dimethylamino)silane), hexakis(ethylamino)disilane (Si₂(NHC₂H₅)₆.

In accordance with further examples of the disclosure, the silicon-containing gas does not include a compound comprising oxygen. In some cases, step 106 includes providing another gas, such as a hydrogen-containing gas (e.g., H₂, NH₃, or the like) within the reaction chamber.

A duration of step 106 of contacting the molybdenum metal layer with a silicon-containing gas can be between 0.1 seconds and 600 seconds, between 10 seconds and 300 seconds, or between 60 seconds and 180 seconds.

In accordance with further examples of the disclosure, the step of depositing the molybdenum metal layer (step 104) and the step of contacting the molybdenum metal layer with a silicon-containing gas (step 106) can be repeated as in cyclical process to form a molybdenum silicide layer of a desired thickness. The repeated cycling between step 104 and 106 can be performed when a molybdenum silicide layer with an increased thickness is desired. For example, the repeated cycling between step 104 and step 106 in cyclical process can be performed to form a molybdenum silicide layer with a thickness greater than 10 nm, or greater than 20 nm, or greater than 30 nm, or greater than 40 nm, or greater than 50 nm, or between 10 nm and 50 nm.

FIG. 4 illustrates a structure 400 after the completion of step 106. As illustrated, a molybdenum silicide layer 402 is formed overlying the contact region 204. As illustrated, the molybdenum silicide layer 402 is formed directly on the contact region 204 without any remainder of the previous molybdenum metal layer 302 (FIG. 3). As previously described herein, prior methods for the formation of molybdenum silicide layers can results in a change in the thickness/doping profile of a layer directly underlying the metal silicide. However, as illustrated in FIG. 4 the underlying contact region 204 maintains its original thickness upon formation of the overlying metal silicide layer 402 and consequently there is no detrimental thickness variation or change in doping profile of the contact region 204. For example, the contact region 204 has an initial thickness prior to forming the molybdenum silicide layer and maintains the initial thickness after converting the total thickness of the molybdenum metal layer to the molybdenum silicide layer 402. Likewise, the contact region 204 has an initial doping concentration profile prior to forming the molybdenum silicide layer 402 and maintains the initial doping concentration profile after converting the entire thickness of the molybdenum metal layer to the molybdenum silicide layer 402.

The molybdenum silicide layer 402 can comprise, consist essentially of, or consist of molybdenum silicide. A layer consisting of molybdenum silicide may include an acceptable amount of impurities, such as carbon, chlorine or other halogen, and/or hydrogen that may originate from one or more precursors used to deposit the molybdenum metal layer and convert the molybdenum metal layer to a molybdenum metal silicide layer by means of providing the silicon-containing gas into the reaction chamber.

An average layer thickness of the molybdenum silicide layer 402 can be, for example, between 1 nm and 50 nm, or between 2 nm and 25 nm, or between 3 nm and 15 nm. In accordance with further examples of the disclosure, the average layer thickness of the molybdenum silicide layer 402 is between 1 nm and 10 nm, or between 2 nm and 8 nm, or between 3 nm and 5 nm. In accordance with further examples of the disclosure, the molybdenum silicide layer is deposited to an average layer thickness of less than 10 nm, or less 8 nm, or less 6 nm, or less than 4 nm, or less than 2 nm, or less than 1 nm.

Method 100 (FIG. 1) can include an optional step 108 for depositing an additional metal layer on the molybdenum silicide layer. During step 108, an additional layer of metal is deposited on the molybdenum silicide layer. In accordance with examples of the disclosure, the additional metal layer can include an additional molybdenum metal layer and is deposited directly on the molybdenum silicide layer. Optional step 108 can be the same or similar as step 104, except step 112 need not be, but can be cyclical. In particular, step 108 can include using any of the oxygen-free molybdenum precursors and reactants noted above in connection with step 114 and/or 116. Step 108 can be a continuous (e.g., CVD process) or can be a cyclical process as described above in connection with step 112. In addition, the oxygen-free molybdenum precursor, the oxygen-free molybdenum precursor flow rate, and the oxygen-free molybdenum precursor flow duration during step 108 can be as described above in connection with step 104. Likewise, the reactant, the reactant flow rate, and the reactant flow duration during step 108 can be as described above in connection with step 104. Similarly, the temperatures and pressures within a reaction chamber can be as described above in connection with step 104.

FIG. 5 illustrates a structure 500 after the completion of step 108. As illustrated, an additional metal layer 502 is deposited overlying the metal silicide layer 402. The additional metal layer 502 can comprise an additional molybdenum metal layer that is deposited directly on the metal silicide layer 402 thereby forming a contact stack 504 comprising the metal silicide layer 402 and the additional molybdenum metal layer 502. As illustrated, the metal silicide layer 402 is disposed directly between the contact region 204 and the additional molybdenum metal layer 502 without any additional intervening layers contacting the contact region 204 and potentially impacting the contact the resistance of the contact stack 504. In accordance with examples of the disclosure, the contact region 204 can comprise a source/drain region of a semiconductor device structure and, as illustrated, the contact stack 504 can be formed directly on the source/drain region of the semiconductor device structure. In such cases, the molybdenum silicide layer is disposed directly between the source/drain region and the additional molybdenum metal layer 502, the molybdenum silicide layer 402 thereby forming an interface layer between the source/drain region and the additional molybdenum metal layer 502. In accordance with examples of the disclosure, the source/drain has an initial thickness prior to forming the contact stack 504 directly on the source/drain region and the source/drain region maintains the initial thickness after the formation of the contact stack 504 directly on the source/drain region. Likewise, the source/drain region has an initial doping concentration profile prior to forming the contact stack 504 directly on the source/drain region and source/drain region maintains the initial doping profile after the formation of the contact stack 504 directly on the source drain region.

The additional molybdenum metal layer 502 can have an average layer thickness between 1 nm and 200 nm, or between 10 nm and 150 nm, or between 25 nm and 100 nm, or between 25 nm and 50 nm. In accordance with examples of the disclosure, the additional molybdenum metal layer 502 can have an average layer thickness between of less than 250 nm, or less 150 nm, or less 100 nm, or less than 50 nm, or less than 25 nm.

In accordance with further examples of the disclosure, the additional metal layer 502 can include an additional tungsten layer or an additional cobalt layer having an average layer thickness between 1 nm and 200 nm, or between 10 nm and 150 nm, or between 25 nm and 100 nm, or between 25 nm and 50 nm. In accordance with examples of the disclosure, the additional tungsten or cobalt metal layer can have an average layer thickness between of less than 250 nm, or less 150 nm, or less 100 nm, or less than 50 nm, or less than 25 nm.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

1. A method of forming a molybdenum silicide layer on a surface of a substrate, the method comprising:
seating a substrate within a reaction chamber;
depositing a molybdenum metal layer on a surface of the substrate; and
contacting the molybdenum metal layer with a silicon-containing gas to convert at least a portion of the molybdenum metal layer to a molybdenum silicide layer.

2. The method of claim 1, wherein the step of depositing the molybdenum metal layer comprises a chemical vapor deposition process.

3. The method of claim 1, wherein the step of depositing the molybdenum metal layer comprises a thermal cyclical deposition process.

4. The method of claim 3, wherein the thermal cyclical deposition process comprises an atomic layer deposition process, each deposition cycle of the atomic layer deposition process comprising:
providing a molybdenum precursor to form an absorbed molybdenum species on the surface of substrate; and
providing a reactant to react with the molybdenum species to form the molybdenum metal layer on the surface of the substrate.

5. The method of claim 4, wherein the molybdenum precursor comprises an oxygen-free molybdenum precursor.

6. The method of claim 5, wherein the oxygen-free molybdenum precursor comprises a molybdenum atom and a bis(ethyl benzene) ligand.

7. The method of claim 6, wherein the oxygen-free molybdenum precursor comprises Mo(EtBz)2.

8. The method according to claim 4, wherein the reactant comprises a compound consisting of a halogen atom and a hydrocarbon group.

9. The method of claim 8, wherein the halogen atom is iodine or bromine.

10. The method of claim 9, wherein the reactant comprises iodobenzene or 1-iodobutane.

11. The method of claim 9, wherein the reactant comprises bromobenzene or 1-bromobutane.

12. The method according to claim 1, wherein the step of depositing the molybdenum metal layer is performed at a substrate temperature between 150° C. and 400° C.

13. The method according to claim 1, wherein the silicon-containing gas has a general formula RₐSiX_{b} or R_{c}X_{d}Si—SiR_{c}X_{d}, where each X can be independently selected from H, a halogen, or other ligand, wherein each R can be a C1-C12 organic group, and where a is 0, 1, 2 or 3, b is 4-a, c is 0, 1 or 2, and d is 3-c.

14. The method according to claim 1, wherein the step of contacting the molybdenum metal layer with the silicon-containing gas is performed at a substrate temperature between 400° C. and 700° C.

15. The method according to claim 1, further comprising a step of depositing an additional molybdenum metal layer on the molybdenum silicide layer.

16. The method according to claim 1, further comprising a step of cleaning the surface of the substrate prior to the step of depositing the molybdenum metal layer.

17. The method of claim 16, wherein the step of cleaning the surface of the substrate comprises contacting the surface of the substrate with a first activated species formed using a fluorine-containing gas and a second activated species formed using a hydrogen-containing or NH₃-containing gas.

18. A semiconductor device structure formed according to the method of claim 1.

19. A method of forming a molybdenum silicide layer on a surface of a substrate, the method comprising:
seating a substrate within a reaction chamber, the substrate including a contact region of a semiconductor device structure;
cleaning a surface of the contact region using a first activated species formed using a fluorine-containing gas and a second activated species formed using a hydrogen-containing or NH₃-containing gas to form a cleaned contact surface;
depositing a molybdenum metal layer directly on the cleaned contact surface by a cyclical deposition process comprising:
heating the substrate to a substrate temperature between 150° C. and 400° C.;
providing an oxygen-free molybdenum precursor to the reaction chamber;
providing a reactant to the reaction chamber;
contacting the molybdenum metal layer with a silicon-containing gas thereby converting at least a portion of the molybdenum metal layer to a molybdenum silicide layer; and
depositing an additional molybdenum metal layer directly on the molybdenum silicide layer.

20. The method of claim 19, wherein the step of contacting the molybdenum metal layer with the silicon-containing gas is performed at a substrate temperature between 400° C. and 700° C.
